(19) United States
(12) Patent Application Publication
(10) Pub. No.: US 2026/0068678 A1
(43) Pub. Date: Mar. 5, 2026

(54) NOVEL ON-PACKAGE ELECTROMAGNETIC ABSORBER

(71) Applicant: Qorvo US, Inc., Greensboro, NC (US)

(72) Inventor: Assaf Aviv Haviv, Frisco, TX (US)

(21) Appl. No.: 19/293,681

(22) Filed: Aug. 7, 2025

Related U.S. Application Data
(60) Provisional application No. 63/733,772, filed on Dec. 13, 2024.
(60) Provisional application No. 63/690,943, filed on Sep. 5, 2024.

(51) Int. Cl. H01L 23/552; H01L 21/52

(52) U.S. Cl. CPC H10W 42/20; H10W 72/071

(57) ABSTRACT

Aspects of the disclosure provide a semiconductor package and a method for preparing the same. The disclosed semiconductor package includes a die disposed over and conductively coupled to a laminate; and a member (e.g., a lid) attached to the laminate via one or more conducting materials. The member includes a structure (e.g., an electromagnetic absorber structure) configured to absorb electromagnetic radiation. In one or more embodiments, a wireless device may include the semiconductor package produced via the method as disclosed herein.

### CROSS-REFERENCE TO RELATED APPLICATIONS

The present application claims the benefit of U.S. Provisional Application Number 63/690,943, entitled “NOVEL ON-PACKAGE ELECTROMAGNETIC ABSORBER” and filed on September 5, 2024, and U.S. Provisional Application Number 63/733,772, entitled “NOVEL ON-PACKAGE ELECTROMAGNETIC ABSORBER” and filed on December 13, 2024, which is hereby incorporated by reference in its entirety.

### TECHNICAL FIELD

The present disclosure relates generally to semiconductor manufacturing methodologies and related implementations, and in particular, relates to systems and methods for preparing a semiconductor package having an on-package electromagnetic absorber.

### BACKGROUND

Advanced semiconductor electronics are typically assembled using cutting-edge manufacturing techniques. As electronic systems become more compact and engineered to operate at higher frequencies, issues related to electromagnetic interference (EMI) become more prominent and pronounced, resulting in performance degradation that leads to signal integrity issues and even component failures. Some of the technical issues with existing technology include, for example, EMI, crosstalk, size and weight constraints, and manufacturing complexity. In current high-density electronic circuits, EMI can degrade signal integrity, leading to errors and reduced performance. Existing shielding methods are often bulky, costly, or insufficient in effectively managing EMI in compact spaces. When multiple chips are placed in close proximity, electromagnetic fields from one chip can interfere with neighboring chips, causing crosstalk. This interference can lead to signal degradation, data corruption, and overall system instability.

Existing methods to improve isolation, such as metal shields or larger packaging designs, can increase the size and weight of electronic devices. Existing isolation techniques often require additional manufacturing steps, which inevitably lead to increasing production complexity and costs. To address these issues, isolation between chips will need to be improved to mitigate electromagnetic interference and crosstalk in densely packed electronic circuits. Thus, there is a need for a system and a method for preparing a package with improved electromagnetic isolation in electronic devices without using additional manufacturing steps or increasing production complexity and costs.

### SUMMARY

Embodiments of the present disclosure include advanced semiconductor manufacturing methodologies for preparing a semiconductor package having an on-package electromagnetic absorber. Aspects of the disclosure advantageously provide a semiconductor package and one or more methods of preparing a semiconductor package for use in wireless devices, wireless communications, and/or radar systems.

In an exemplary aspect, a semiconductor package is provided. The semiconductor package includes a die disposed on a laminate; an interposer disposed between the die and the laminate, the interposer comprising a plurality of vias configured for electrical connections between the die and the laminate; and a member attached to the interposer via one or more conducting materials, the member comprising a structure configured to absorb electromagnetic radiation.

In one or more embodiments, the member and the interposer may include silicon carbide. In one or more embodiments, the member may include one or more protruding edges that attach to the interposer in a configuration such that the attachment forms a cavity that surrounds the die therewithin. In one or more embodiments, the structure may include a gold film and absorbs electromagnetic radiation emitted from the die during operation of the die. In one or more embodiments, the structure may be disposed on a surface of the member facing the die. In one or more embodiments, the structure may be disposed on a surface of the member facing away from the die.

In one or more embodiments, the die may include a radio frequency monolithic microwave integrated circuit configured to operate in a range of frequency between 50 GHz and 150 GHz. In one or more embodiments, the structure may include a shape and/or a pattern designed to absorb and cancel out specific frequencies of radiation within the range of frequency between 50 GHz and 150 GHz.

In an exemplary aspect, a method for preparing a semiconductor package is provided. The method may include disposing an interposer on a laminate; disposing a die atop the interposer, wherein the interposer comprises a plurality of vias configured for electrical connections between the die and the laminate; and attaching a member to the interposer via one or more conducting materials, wherein the member comprises a structure configured to absorb electromagnetic radiation.

In one or more embodiments of the provided method, the member and the interposer may include silicon carbide. In one or more embodiments of the provided method, the member may include one or more protruding edges for attaching to the interposer in a configuration such that the attachment forms a cavity that surrounds the die therewithin. In one or more embodiments, the structure may include a gold film and absorbs electromagnetic radiation emitted from the die during operation of the die. In one or more embodiments, the structure may be disposed on a surface of the member facing the die. In one or more embodiments, the structure may be disposed on a surface of the member facing away from the die.

In one or more embodiments of the provided method, the die may include a radio frequency monolithic microwave integrated circuit configured to operate in a range of frequency between 50 GHz and 150 GHz. In one or more embodiments, the structure may include a shape and/or a pattern designed to absorb and cancel out specific frequencies of radiation within the range of frequency between 50 GHz and 150 GHz.

In an exemplary aspect, a wireless device comprising a semiconductor package is provided. The semiconductor package of the wireless device includes a die disposed on a laminate; an interposer disposed between the die and the laminate, the interposer comprising a plurality of vias configured for electrical connections between the die and the laminate; and a lid attached to the interposer via one or more conducting materials, the lid comprising an absorber configured to absorb electromagnetic radiation.

In one or more embodiments of the wireless device, the lid and the interposer may include silicon carbide, and wherein the lid may include one or more protruding edges that attach to the interposer in a configuration such that the attachment forms a cavity that surrounds the die therewithin. In one or more embodiments of the wireless device, the absorber may include a gold film and absorbs electromagnetic radiation emitted from the die during operation of the die. In one or more embodiments, the absorber may be disposed on a surface of the lid facing the die or on a surface of the lid facing away from the die. In one or more embodiments, the die may include a radio frequency monolithic microwave integrated circuit configured to operate in a range of frequency between 50 GHz and 150 GHz. In one or more embodiments, the absorber may include a shape and/or a pattern designed to absorb and cancel out specific frequencies of radiation within the range of frequency between 50 GHz and 150 GHz.

Additional aspects, embodiments, implementations, features, and advantages of the present disclosure will become apparent from the following detailed description.

### BRIEF DESCRIPTION OF THE DRAWINGS

Illustrative embodiments of the present disclosure will be described with reference to the accompanying drawings, of which:

FIG. 1 illustrates a cross-sectional view of an example semiconductor package, according to aspects of the present disclosure.

FIG. 2A illustrates a perspective view of an example semiconductor package, according to aspects of the present disclosure.

FIG. 2B illustrates a perspective view of an example semiconductor package, according to aspects of the present disclosure.

FIG. 2C illustrates a perspective view of an example semiconductor package, according to aspects of the present disclosure.

FIGS. 3A, 3B, 3C, and 3D are plots showing simulation results of example semiconductor packages, according to aspects of the present disclosure.

FIG. 4A illustrates a perspective view of a configuration having two example semiconductor packages next to one another, according to aspects of the present disclosure.

FIG. 4B illustrates a perspective view of a configuration having two example semiconductor packages next to one another, according to aspects of the present disclosure.

FIGS. 5A, 5B, and 5C are plots showing simulation results of the example semiconductor packages shown in FIGS. 4A and 4B, according to aspects of the present disclosure.

FIG. 6 illustrates a flowchart for a method for preparing an example semiconductor package, according to aspects of the present disclosure.

FIG. 7 illustrates an electronic device or a wireless device comprising a semiconductor package, according to aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

As used herein, the term “couple to” may refer to that two components are linked such that they can affect or interact with each other. The coupling/link between the two components may include direct connections (e.g., linked by direct contact) or indirect connections (e.g., linked via an intermediate component). In various embodiments, a coupling between two components may include electrical connections, mechanical connections, or a combination thereof.

Embodiments of the present disclosure include advanced semiconductor manufacturing methodologies for preparing a semiconductor package having an on-package electromagnetic absorber. The disclosed semiconductor package may include an electromagnetic absorber that can be printed directly onto one or more areas of the semiconductor package. The disclosed absorber technology aims to increase isolation between packages and radio frequency (RF) devices, thereby mitigating electromagnetic interference (EMI) and crosstalk, which are common issues in densely packed electronic circuits. The disclosed absorber can improve isolation between these devices, ensuring that each device operates within its designated electromagnetic environment, thus improving overall system performance and reliability.

In accordance with one or more embodiments, the disclosed electromagnetic absorber is designed to be integrated directly into the packaging of semiconductor devices. By being printed on top or inside of the semiconductor packages, it directly targets and absorbs unwanted electromagnetic waves that could interfere with the performance of nearby devices. Integrating the absorber directly into the chip packaging via printing simplifies the manufacturing process and reduces associated costs. By addressing these issues, this electromagnetic absorber technology may offer a novel solution that is not only effective in improving device isolation, but also aligns with the industry's push towards more compact, lightweight, and cost-effective electronic designs.

In one or more embodiments, the disclosed electromagnetic absorbers are designed using the principles of metamaterials. Metamaterials are artificially engineered materials that have unique properties not found in naturally occurring materials. These properties arise from the material's structure rather than its composition. By precisely designing the shape, size, and arrangement of the components within the material, metamaterials can manipulate electromagnetic waves in ways that conventional materials cannot.

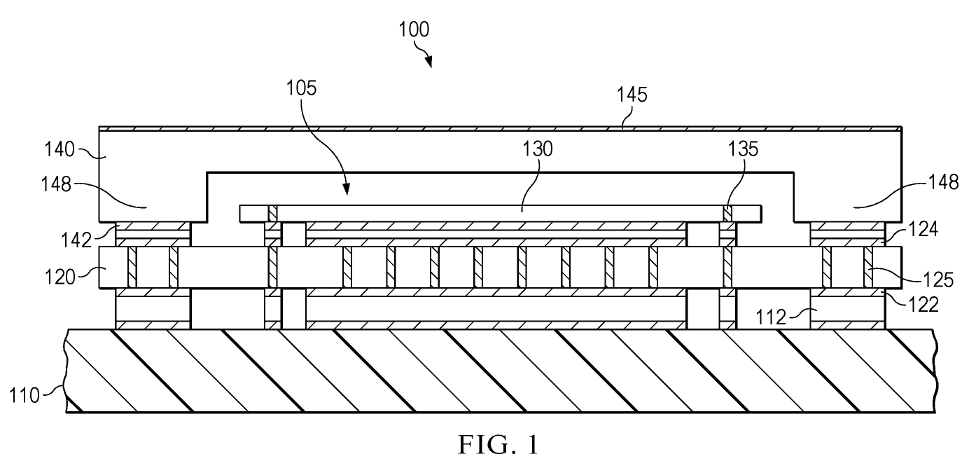

Various embodiments of the disclosed packaging and methodologies are described below in further detail with respect to the FIGS. 1-7.

FIG. 1 illustrates a cross-sectional view of an example semiconductor package 100, according to aspects of the present disclosure. In one or more embodiments, the semiconductor package 100 may include a wide band gap semiconductor package with advanced semiconductor manufacturing. In some embodiments, the semiconductor package 100 may be produced or manufactured using advanced semiconductor packaging techniques as disclosed herein.

As illustrated in FIG. 1, the semiconductor package 100 includes a laminate 110, which may comprise an organic composite, in accordance with one embodiment. The semiconductor package 100 includes an interposer 120 disposed atop, or attached to, the laminate 110 via solder 112 (e.g., solder alloy 305SAC) and a land grid array (LGA) pad 122, as shown in FIG. 1. In one or more embodiments, the solder 112 may have a thickness between 50 µm and 75 µm, inclusive of any thickness values therebetween. In one or more embodiments, the LGA pad 122 may include a gold/copper/nickel/gold layer having a thickness between 5 µm and 10 µm, inclusive of any thickness values therebetween. In one or more embodiments, the interposer 120 may include silicon carbide.

As further illustrated in FIG. 1, the semiconductor package 100 includes a die 130 disposed atop, or attached to, the interposer 120. In one or more embodiments, the interposer 120 includes a plurality of vias 125 (also referred to herein as hot vias), which are vertical through-vias across the thickness of the interposer 120. In various embodiments, the vias 125 are configured for electrical connections between the die 130 and the laminate 110, as shown in FIG. 1. In one or more embodiments, one or more of the vias 125 may be electrically connected to one or more hot vias 135 of the die 130, as shown in FIG. 1.

As further illustrated in FIG. 1, the semiconductor package 100 includes a member 140 (also referred to herein as a lid, a cover, or a cover member) attached to the interposer 120 via one or more conducting materials 124 and 142. In one or more embodiments, the member 140 may include silicon carbide. In one or more embodiments, the conducting material 124 may include a plated tin and gold layer that has a thickness of about 15 µm. In one or more embodiments, the conducting material 142 may include a gold film or a gold layer.

In one or more embodiments, the member or lid 140 may include an absorber structure 145 (also referred to herein as an absorber, a structure, or an electromagnetic absorber structure) configured to absorb electromagnetic radiation. In one or more embodiments, the absorber structure 145 absorbs electromagnetic radiation emitted from the die 130 during operation of the die. In one or more embodiments, the absorber structure 145 may include a gold film or a gold layer. In one or more embodiments, the absorber structure 145 may have a thickness of about 1 µm, about 2 µm, about 3 µm, about 4 µm, about 5 µm, about 6 µm, about 7 µm, about 8 µm, about 9 µm, about 10 µm, or any thickness values therebetween.

In one or more embodiments, the member or lid 140 may include one or more protruding edges 148 that attach to the interposer 120 in a configuration, as shown in FIG. 1, such that the attachment forms a cavity 105 that surrounds the die 130 therewithin. In one or more embodiments, the structure 145 is disposed on a surface of the member or lid 140 facing the die; that is, the structure 145 is disposed on the inside of the cavity 105. In one or more embodiments, the structure is disposed on a surface of the member or lid 140 facing away from the die; that is, the structure 145 is disposed on the lid 140 outside of the cavity 105.

In one or more embodiments, the die 130 may include a radio frequency monolithic microwave integrated circuit (MMIC). The MIMC may be configured to operate in a range of frequency between 50 GHz and 150 GHz, between 70 GHz and 130 GHz, between 90 GHz and 110 GHz, or any frequence ranges therebetween. In one or more embodiments, the absorber structure 145 may include a shape and/or a pattern designed to absorb and cancel out specific frequencies of radiation within the range of frequency between 50 GHz and 150 GHz, between 70 GHz and 130 GHz, between 90 GHz and 110 GHz, or any frequence ranges therebetween. In one or more embodiments,

In one or more embodiments, the absorber structure 145 may be designed to operate within the 90-100 GHz frequency range, targeting high-frequency applications where electromagnetic interference (EMI) is a critical concern. In one or more embodiments, the absorber structure 145 may be precisely shaped to reduce radiation emitted by the die 130, i.e., the MMIC within the semiconductor package 100. In some embodiments, during the operation of the die 130, it generates electromagnetic radiation that can escape the package 100 and cause interference in surrounding components. The design of the absorber structure 145, including its shape and the spacing between its elements, is engineered to effectively capture and cancel out this radiation, achieving a reduction of 10 dB - 15 dB compared to a semiconductor package without an absorber structure.

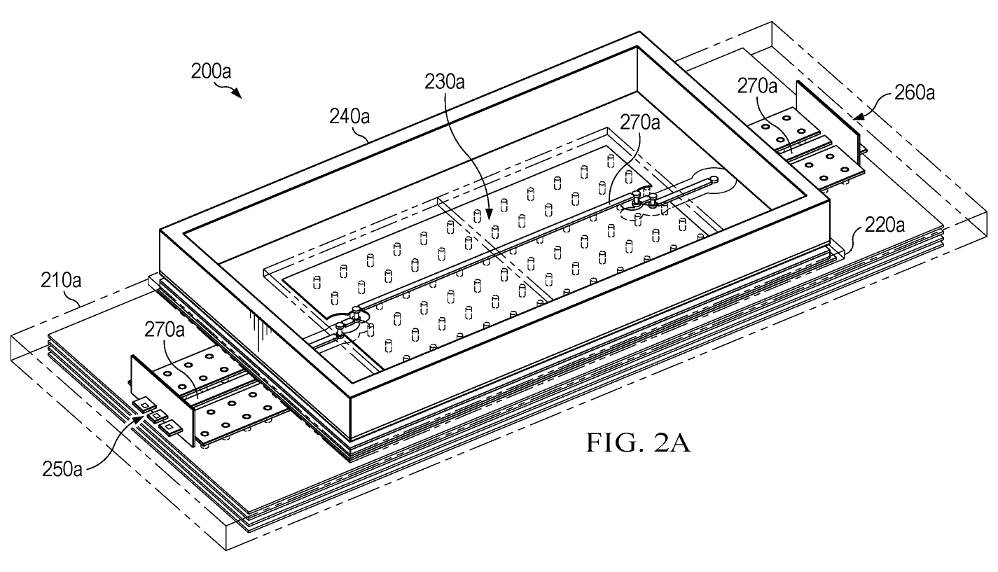

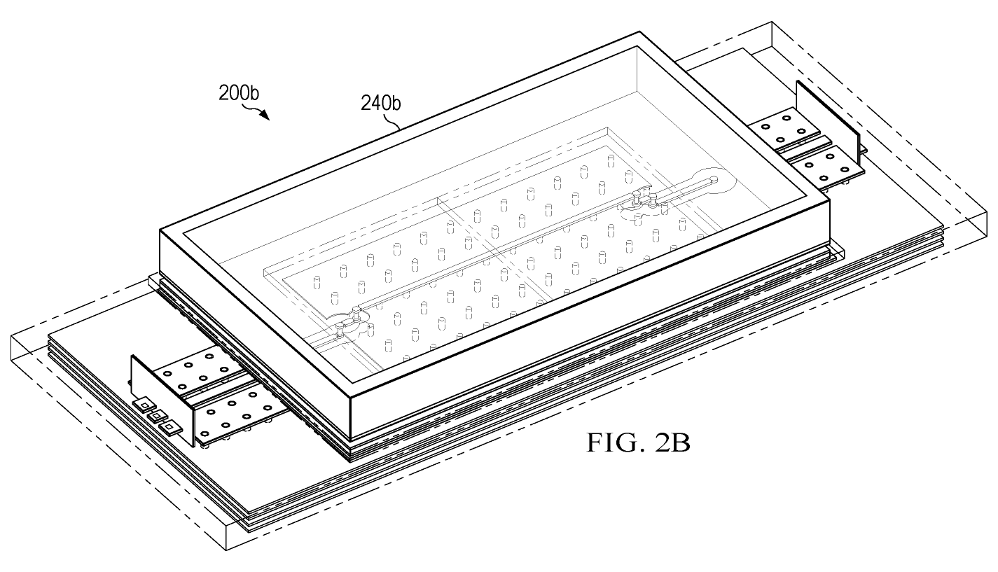

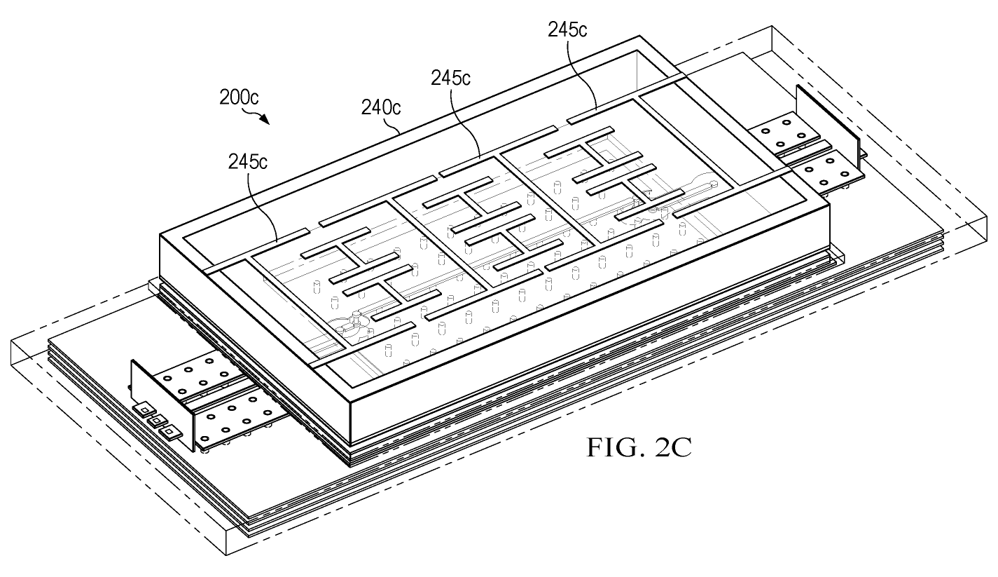

FIG. 2A illustrates a perspective view of an example semiconductor package 200a, FIG. 2B illustrates a perspective view of an example semiconductor package 200b without an absorber structure, and FIG. 2C illustrates a perspective view of an example semiconductor package 200c with an absorber structure 245c, according to aspects of the present disclosure. In one or more embodiments, the semiconductor packages 200a, 200b, and 200c may include a wide band gap semiconductor package with advanced semiconductor manufacturing. In some embodiments, the semiconductor packages 200a, 200b, and 200c may be produced or manufactured using advanced semiconductor packaging techniques as disclosed herein.

As illustrated in FIGS. 2A, the semiconductor package 200a includes a die 230a disposed on an interposer 220a, which is disposed on a laminate 210a, which may comprise an organic composite, in accordance with one embodiment. In the example semiconductor package 200a, the die 230a connected to an input port 250a configured for inputting a signal and an output port 260a configured for outputting the signal, where a transmission line 270a is connected between the two ports 250a and 260a, as shown in FIG. 2A. In some embodiments, the transmission line 270a is a 50 Ohm signal transmission line.

As further illustrated in FIG. 2A, the semiconductor package 200a includes a member 240a (also referred to herein as a lid, a cover, or a cover member) attached to the interposer 220a. The semiconductor package 200b illustrated in FIG. 2B includes a lid or member 240b with the without an absorber structure and the semiconductor package 200c illustrated in FIG. 2C includes a lid or member 240c with an absorber structure 245c. In one or more embodiments, the semiconductor package 200c is the semiconductor package 200a with the absorber structure 245c disposed on the lid or member 240c, as shown in FIG. 2C, wherein the absorber structure 245c can be disposed inside or outside the lid or member 240c.

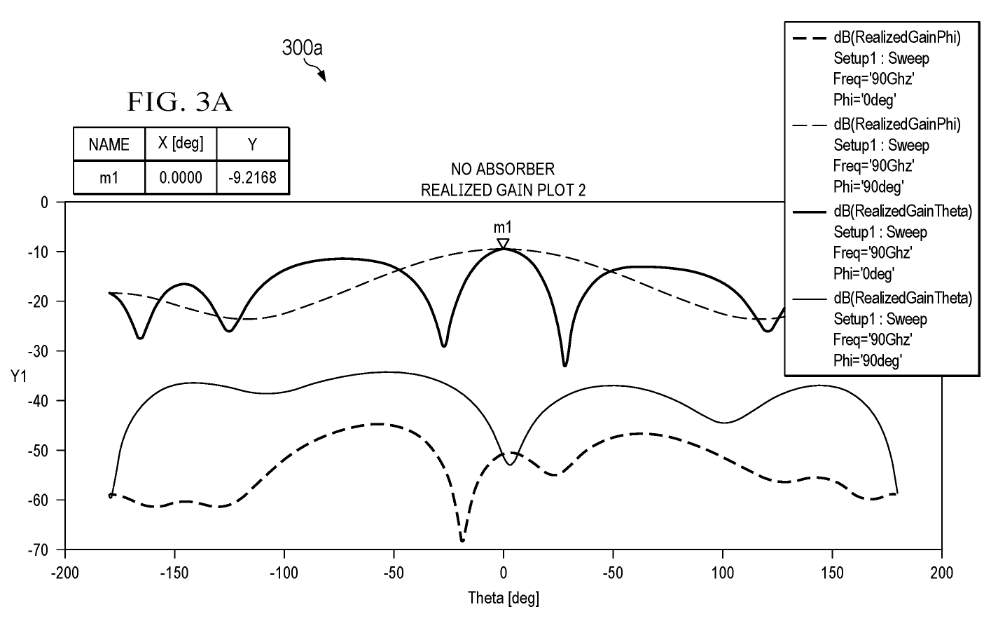

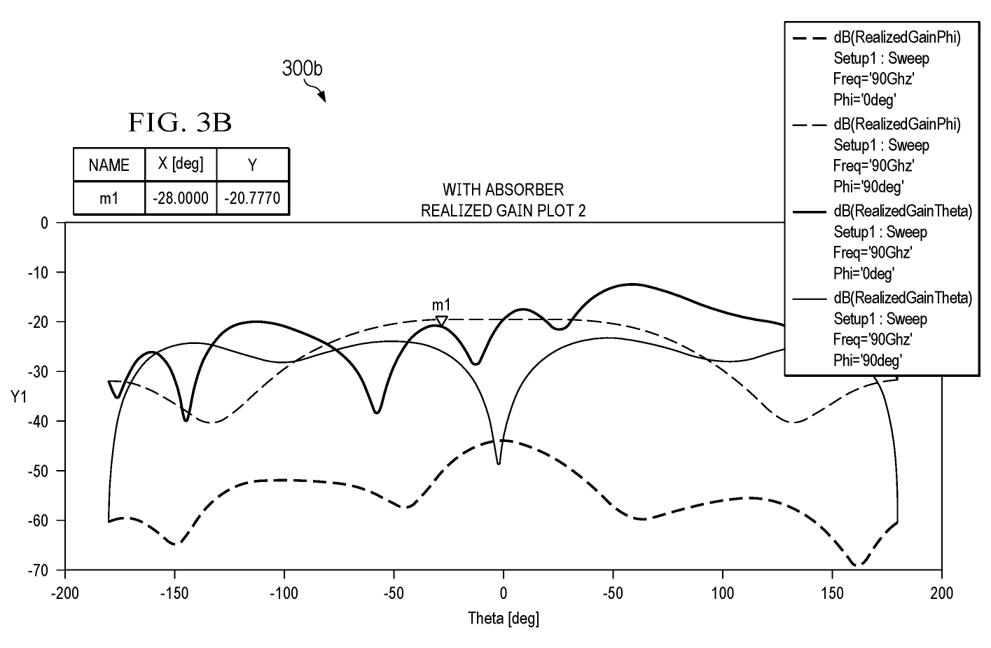

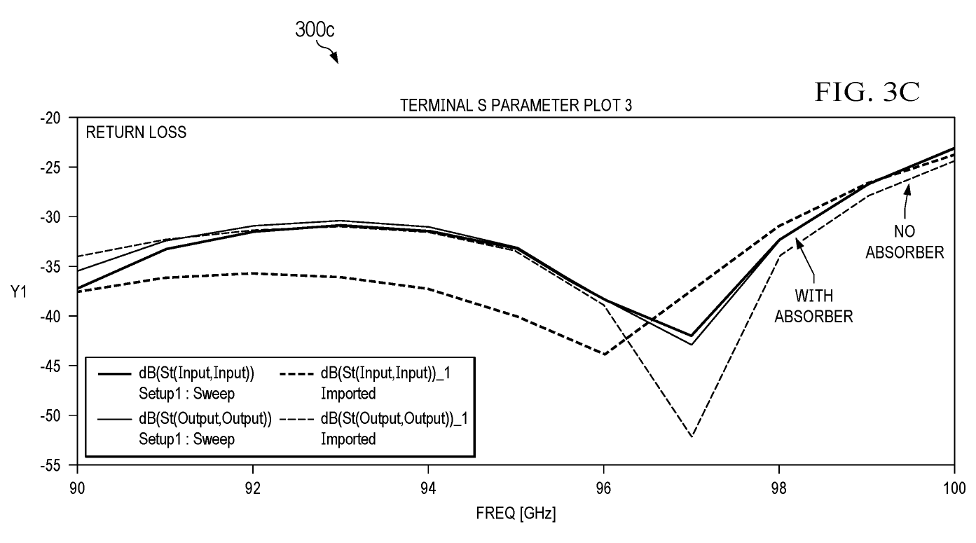

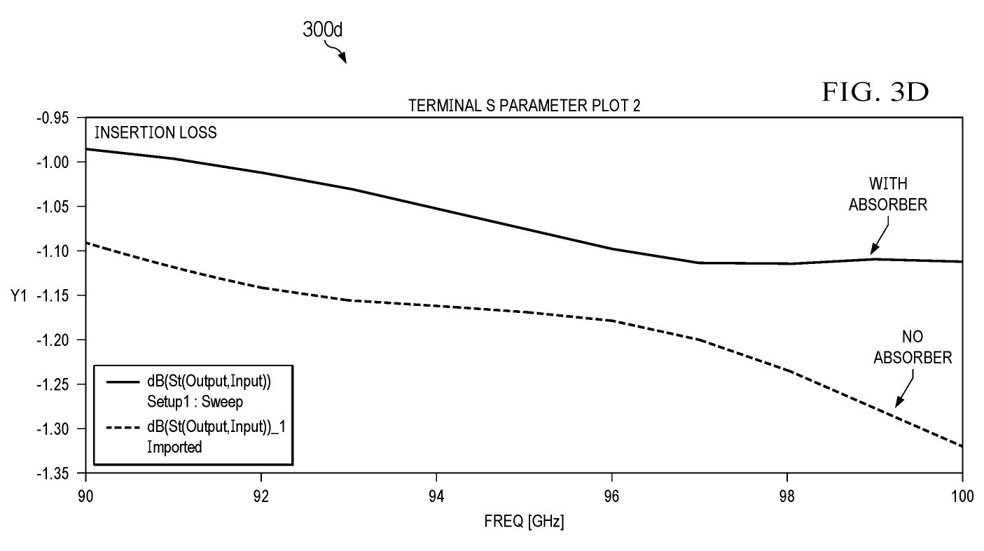

FIGS. 3A, 3B, 3C, and 3D are plots showing simulation results of example semiconductor packages, according to aspects of the present disclosure. Specifically, FIG. 3A shows plot 300a displaying simulation results of radiation patterns at 90 GHz in semiconductor package 200b of FIG. 2B without an absorber. FIG. 3B shows plot 300a displaying simulation results of radiation patterns at 90 GHz in semiconductor package 200c of FIG. 2C with the absorber structure 245c. Comparison of the simulation results in plots 300a and 300b show a reduction of 10dB on average in radiated gain at all angles for the semiconductor package 200c with the absorber structure 245c. FIGS. 3C shows plot 300c displaying the return loss in the performance of the semiconductor package 200b without the absorber structure. FIGS. 3D shows plot 300d displaying the insertion loss in the performance of the semiconductor package 200c with the absorber structure 245c.

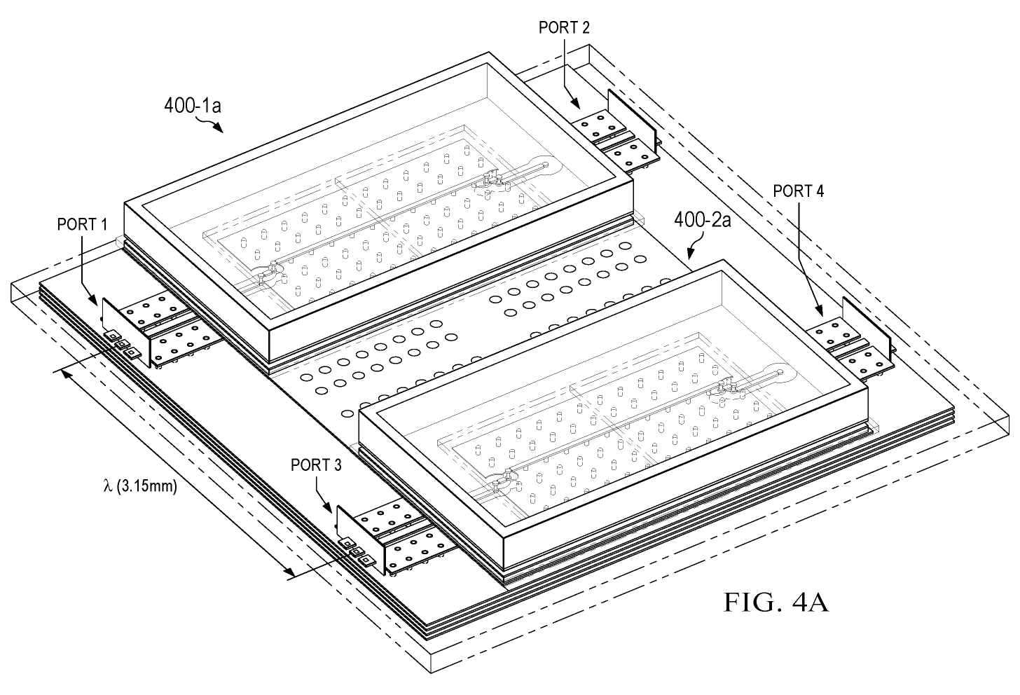

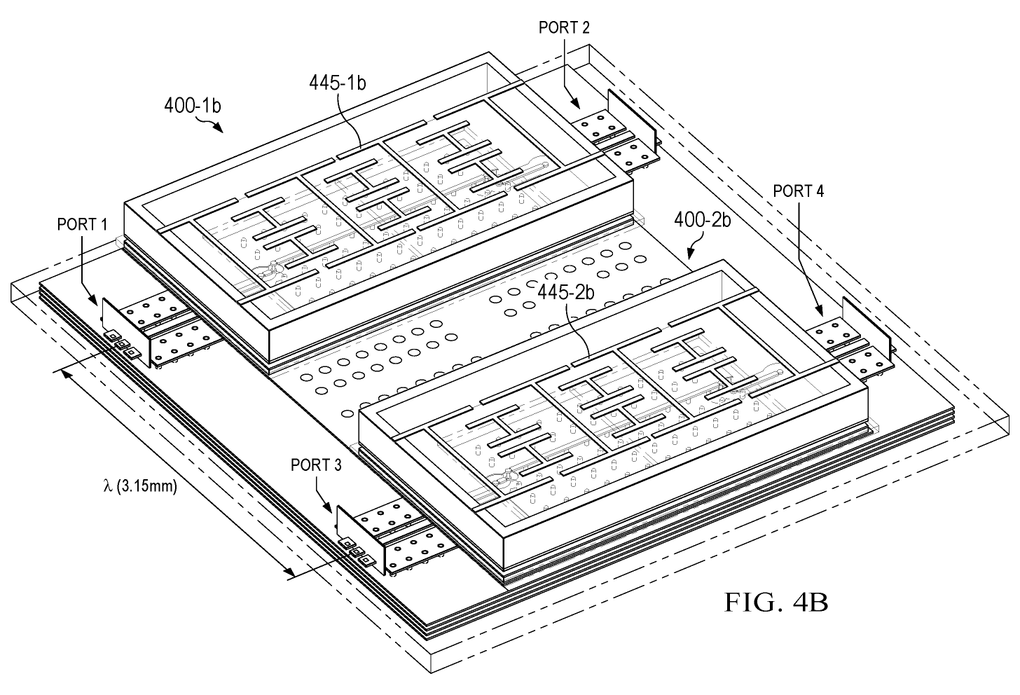

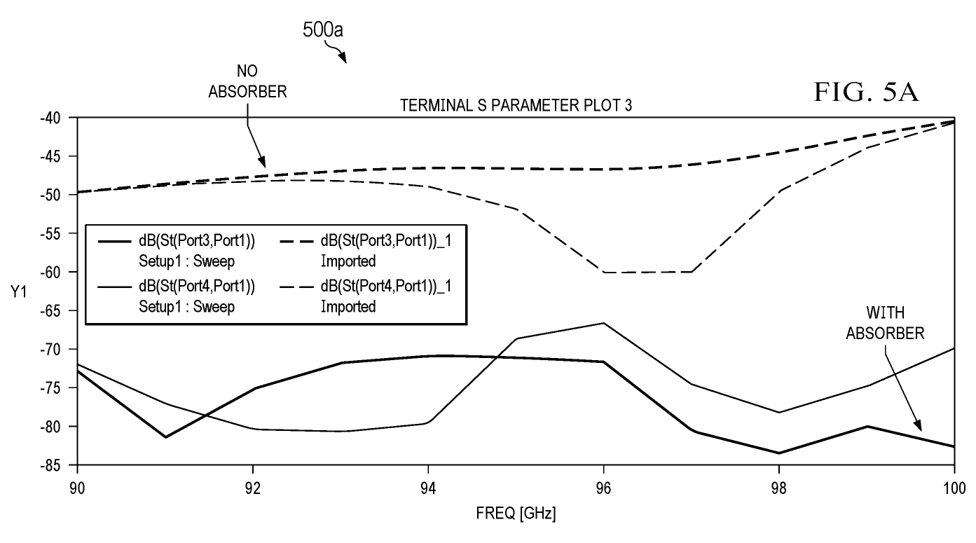

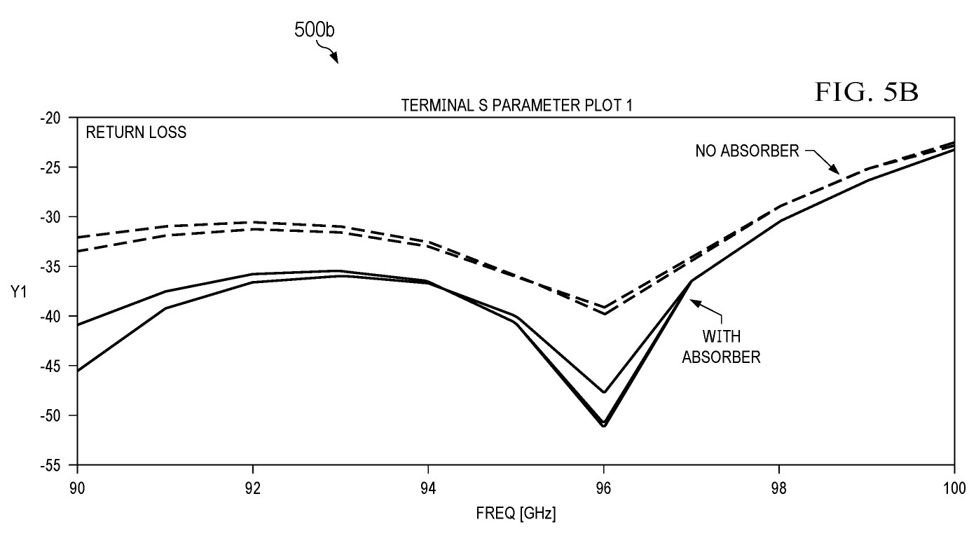

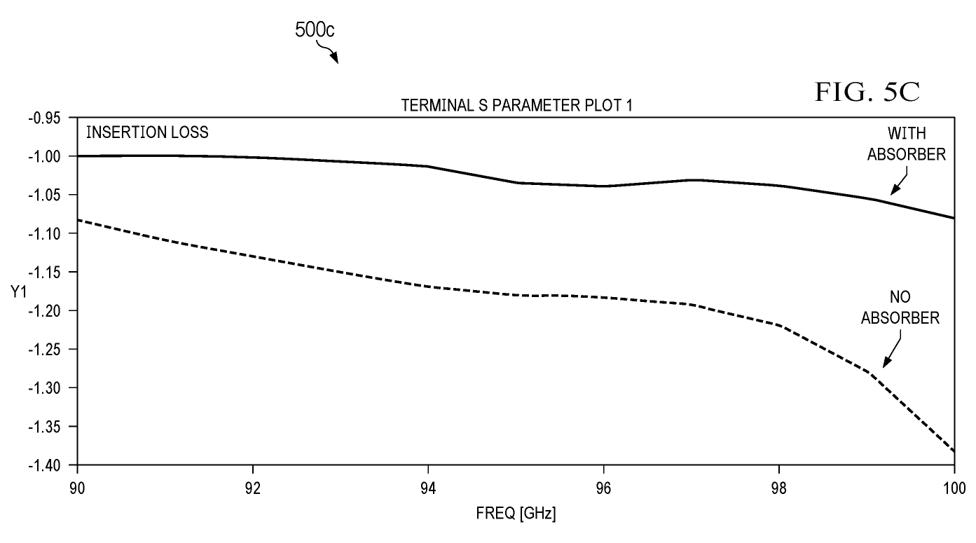

FIG. 4A illustrates a perspective view of a configuration having two example semiconductor packages 400-1a and 400-2a next to one another, but without an absorber structure, according to aspects of the present disclosure. FIG. 4B illustrates a perspective view of a configuration having two example semiconductor packages 400-1b and 400-2b with respective absorber structures 445-1b and 445-2b, according to aspects of the present disclosure. As shown in FIGS. 4A and 4B, the semiconductor packages are placed at one wavelength spacing apart (e.g., 3.15 millimeter) and simulations are performed to illustrate how the disclosed absorber technology can significantly reduce coupling between the semiconductor packages that are placed adjacent to one another. The simulation results, as shown below in FIGS. 5A-5C, exemplify that the use of the absorber help achieve an average reduction of 25 dB in signal coupling between adjacent semiconductor packages.

FIGS. 5A, 5B, and 5C are plots showing simulation results of the example semiconductor packages shown in FIGS. 4A and 4B, according to aspects of the present disclosure. Specifically, FIG. 5A shows plot 500a displaying simulation results of on-package coupling in semiconductor packages 400-1b and 400-2b with respective absorber structures 445-1b and 445-2b. FIG. 5B shows plot 500b displaying the return loss in the performance of the semiconductor packages 400-1a and 400-2a without an absorber structure. FIGS. 5C shows plot 500c displaying the insertion loss in the performance of the semiconductor packages 400-1b and 400-2b with respective absorber structures 445-1b and 445-2b.

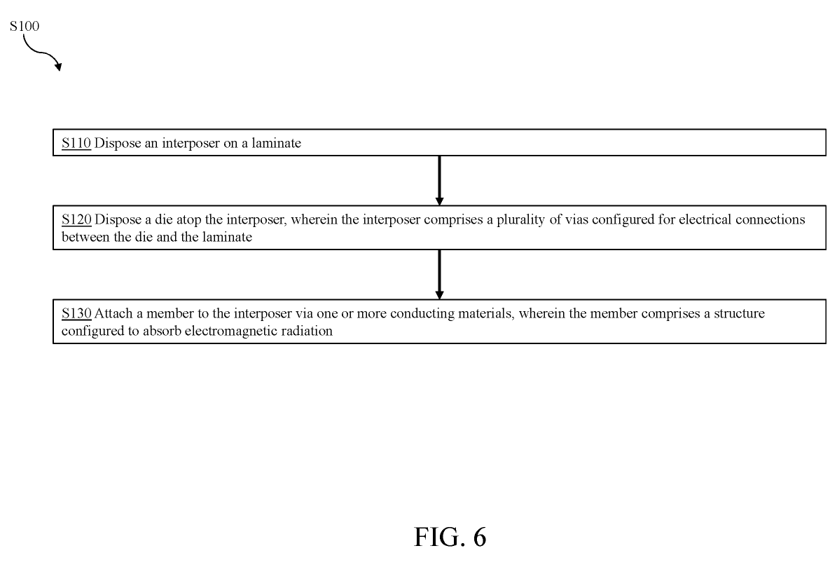

FIG. 6 illustrates a flowchart for a method S100 for preparing an example semiconductor package, according to aspects of the present disclosure. In one or more embodiments, the example semiconductor package prepared using the method S100 may include a semiconductor package, such as the semiconductor packages 100, 200a and 200c, 400-1b and 400-2b, as described with respect to FIGS. 1, 2A, 2C, and 4B. Similar to the semiconductor packages 100, 200a and 200c, 400-1b and 400-2b, the example semiconductor package includes an on-package electromagnetic absorber, according to aspects of the present disclosure. In one or more embodiments, a wireless device may include a semiconductor package, such as semiconductor packages 100, 200a and 200c, 400-1b and 400-2b, produced using the method S100 described herein.

As shown in FIG. 6, the method S100 for preparing the example semiconductor package includes, at step S110, disposing an interposer on a laminate. In one or more embodiments, the interposer may be an interposer, such as the interposers 120 or 220a and the laminate may be a laminate, such as the laminate 110 or 210a. The method S100 further includes, at step S120, disposing a die atop the interposer, wherein the interposer comprises a plurality of vias configured for electrical connections between the die and the laminate. In one or more embodiments, the die may be a die, such as the die 130 or 230a, and the vias may be vias, such as the vias 125 as described in FIG. 1. The method S100 also includes, at step S130, attaching a member to the interposer via one or more conducting materials, wherein the member comprises a structure or an absorber structure configured to absorb electromagnetic radiation. In one or more embodiments, the member may be a member, such as the members or lids 140, 240a, or 240c, and the structure or the absorber structure may be a structure or an absorber structure, such as the absorber structure/structure 145, 245c, 445-1b, or 445-2b, as described with respect to FIGS. 1, 2A, 2C, and 4B.

In one or more embodiments of the method S100, the member and the interposer may include silicon carbide. In one or more embodiments of the method S100, the member may include one or more protruding edges for attaching to the interposer in a configuration such that the attachment forms a cavity that surrounds the die therewithin. In one or more embodiments, the structure may include a gold film and absorbs electromagnetic radiation emitted from the die during operation of the die. In one or more embodiments, the structure may be disposed on a surface of the member facing the die. In one or more embodiments, the structure may be disposed on a surface of the member facing away from the die.

In one or more embodiments of the method S100, the die may include a radio frequency monolithic microwave integrated circuit configured to operate in a range of frequency between 50 GHz and 150 GHz. In one or more embodiments, the structure may include a shape and/or a pattern designed to absorb and cancel out specific frequencies of radiation within the range of frequency between 50 GHz and 150 GHz.

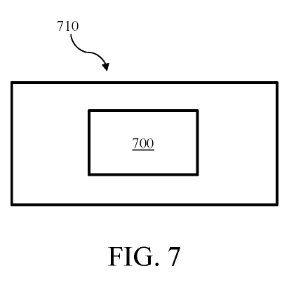

FIG. 7 illustrates an electronic device or a wireless device 710 comprising a semiconductor package 700, according to aspects of the present disclosure. In some implementations, the electronic device or wireless device 710 may include, for example, but not limited to, a computer, a cellular device, a satellite communication device, a wi-fi device, a radar, a global position system device, or any wireless device. In one or more embodiments, the semiconductor package 700 may include a semiconductor package, such as the semiconductor packages 100, 200a and 200c, 400-1b and 400-2b, as described with respect to FIGS. 1, 2A, 2C, and 4B. The semiconductor package 700 may implement any RF component used in wireless applications, as an example, such as one or more RF power amplifiers or in a radar or radar systems; and the semiconductor package 700 may be coupled to other circuitry for implementing a wireless application.

In one or more embodiments, the semiconductor package 700 of the wireless device 710 includes a die disposed on a laminate; an interposer disposed between the die and the laminate, the interposer comprising a plurality of vias configured for electrical connections between the die and the laminate; and a lid attached to the interposer via one or more conducting materials, the lid comprising an absorber configured to absorb electromagnetic radiation.

In one or more embodiments of the wireless device 710, the lid and the interposer may include silicon carbide, and wherein the lid may include one or more protruding edges that attach to the interposer in a configuration such that the attachment forms a cavity that surrounds the die therewithin. In one or more embodiments of the wireless device 710, the absorber may include a gold film and absorbs electromagnetic radiation emitted from the die during operation of the die. In one or more embodiments, the absorber may be disposed on a surface of the lid facing the die or on a surface of the lid facing away from the die. In one or more embodiments, the die may include a radio frequency monolithic microwave integrated circuit configured to operate in a range of frequency between 50 GHz and 150 GHz. In one or more embodiments, the absorber may include a shape and/or a pattern designed to absorb and cancel out specific frequencies of radiation within the range of frequency between 50 GHz and 150 GHz.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

1. A semiconductor package comprising:
a die disposed over and conductively coupled to a laminate; and
a member coupled to the laminate via one or more conducting materials, the member comprising a structure configured to absorb electromagnetic radiation.

2. The semiconductor package of claim 1, wherein the member comprises silicon carbide.

3. The semiconductor package of claim 1, wherein the member comprises one or more protruding edges that couple to the laminate in a configuration such that the coupling forms a cavity that surrounds the die therewithin.

4. The semiconductor package of claim 1, wherein the structure comprises a gold film and absorbs electromagnetic radiation emitted from the die during operation of the die.

5. The semiconductor package of claim 1, wherein the structure is disposed on a surface of the member facing the die.

6. The semiconductor package of claim 1, wherein the structure is disposed on a surface of the member facing away from the die.

7. The semiconductor package of claim 1, wherein the die comprises a radio frequency monolithic microwave integrated circuit configured to operate in a range of frequency between 50 GHz and 150 GHz.

8. The semiconductor package of claim 7, wherein the structure comprises a shape and/or a
pattern designed to absorb and cancel out specific frequencies of radiation within the range of
frequency between 50 GHz and 150 GHz.

9. A method for preparing a semiconductor package, comprising:
disposing a die atop a laminate, wherein the die is conductively coupled to the laminate through a plurality of vias configured for electrical connections; and
attaching a member over the laminate via one or more conducting materials, wherein the member comprises a structure configured to absorb electromagnetic radiation.

10. The method of claim 9, wherein the member comprises silicon carbide.

11. The method of claim 9, wherein the member comprises one or more protruding edges for coupling to the member in a configuration such that the coupling forms a cavity that surrounds the die therewithin.

12. The method of claim 9, wherein the structure comprises a gold film and absorbs electromagnetic radiation emitted from the die during operation of the die.

13. The method of claim 9, wherein the structure is disposed on a surface of the member facing the die.

14. The method of claim 9, wherein the structure is disposed on a surface of the member facing away from the die.

15. The method of claim 9, wherein the die comprises a radio frequency monolithic microwave integrated circuit configured to operate in a range of frequency between 50 GHz and 150 GHz.

16. A wireless device comprising a semiconductor package, the semiconductor package comprising:
a die disposed over and conductively coupled to a laminate; and
a lid attached to the laminate via one or more conducting materials, the lid comprising an absorber configured to absorb electromagnetic radiation.

17. The wireless device of claim 16, wherein the lid comprises silicon carbide, and wherein the lid comprises one or more protruding edges that attach to the laminate in a configuration such that the attachment forms a cavity that surrounds the die therewithin.

18. The wireless device of claim 16, wherein the absorber comprises a gold film and absorbs electromagnetic radiation emitted from the die during operation of the die.

19. The wireless device of claim 16, wherein the absorber is disposed on a surface of the lid facing the die or on a surface of the lid facing away from the die.

20. The wireless device of claim 16, wherein the die comprises a radio frequency monolithic
microwave integrated circuit configured to operate in a range of frequency between 50 GHz and
150 GHz, and wherein the absorber comprises a shape and/or a pattern designed to absorb and
cancel out specific frequencies of radiation within the range of frequency between 50 GHz and
150 GHz.
